(19) United States
(12) Patent Application Publication
(10) Pub. No.: US 2005/0184361 A1
(43) Pub. Date: Aug. 25, 2005

(54) Vertical bipolar transistor and method of manufacturing the same

(75) Inventor: Gen Sasaki, Yamato-shi (JP)

Correspondence Address: FOLEY AND LARDNER;SUITE 500, 3000 K STREET NW, WASHINGTON, DC, 20007, US

(73) Assignee: KABUSHIKI KAISHA TOSHIBA

(21) Appl. No.: 10/863,521

(22) Filed: Jun. 9, 2004

(30) Foreign Application Priority Data
Feb. 20, 2004 (JP) 2004-044209

(51) Int. Cl. H01L 29/76

(52) U.S. Cl. 257/565

(57) ABSTRACT

A vertical bipolar transistor comprises P-type semiconductor substrate, N-type first well provided in the semiconductor substrate and operating as a collector, P-type second well provided on the first well and operating as a base, N-type third well provided on the first well and acting as a lead-out region of the collector, N-type emitter provided in the second well, an isolation structure provided on the second well to define the emitter, P-type base lead-out region provided in the second well to surround the isolation structure, a first insulating isolation layer provided in the second and third wells to define, along with the isolation structure, the base lead-out region, N-type collector lead-out region provided in the third well and adjoining the first insulating isolation layer, and a second insulating isolation layer provided in the third well to define the collector lead-out region.

### CROSS-REFERENCE TO RELATED APPLICATIONS

This application is based upon and claims the benefit of priority from prior Japanese Patent Application No. 2004-044209, filed Feb. 20, 2004, the entire contents of which are incorporated herein by reference.

### BACKGROUND OF THE INVENTION

1. Field of the Invention

The present invention relates generally to a semiconductor device and a method of manufacturing the same, and more particularly to a vertical bipolar transistor and a method of manufacturing the same.

2. Description of the Related Art

In a conventional circuit that requires no high-performance bipolar transistor, a bipolar transistor, which can be manufactured without adding a fabrication step in a CMOS process, is employed in order to reduce the manufacturing cost.

In this technique, a source/drain region of a first conductivity type is used as an emitter region. A well region of a second conductivity type, where the sour/drain region is formed, is used as a base region, and a well region of the first conductivity type is used as a collector region.

FIGS. 13 to 17 illustrate fabrication steps of such a prior-art bipolar transistor.

As is shown in FIG. 13, isolation regions (STI) 51 are selectively formed in, e.g. a P-type silicon substrate 50. Then, a deep N-type well region 52, which functions as a collector region of the bipolar transistor, a P-type well region 53, which functions as a base region, and an N-type well region 54, which becomes a lead-out region for the collector region, are formed in succession.

Although a CMOS section is simply described without depiction on drawings, the P-type well region 53 corresponds to an N-channel MOSFET formation region in the CMOS section, and the N-type well region 54 corresponds to a P-channel MOSFET formation region in the CMOS section.

As is shown in FIG. 14, an N⁺ emitter region 55 and an N⁺ collector lead-out region 56 are selectively formed. These are formed at the same time as N⁺ source/drain regions of the N-channel MOSFET in the CMOS section.

As illustrated in FIG. 15, a P⁺ base lead-out region 57 is selectively formed. This is formed at the same time as P⁺ source/drain regions of the P-channel MOSFET in the CMOS section. Thereafter, a silicide film 58 is formed on the surface of each diffusion region by a saliciding process.

In a step shown in FIG. 16, after an insulation film 59 is deposited over the surface of the substrate, conductor layers 60, which are connected to the N+region 55, 56 and P⁺ region 57, are formed in the insulation film 59 by an ordinary electrode forming process. Thus, the bipolar transistor is completed.

In the bipolar section, as shown in FIG. 17, the N⁺ emitter region 55, N⁺ collector lead-out region 56 and P⁺ base lead-out region 57 are formed in the silicon regions lying among the isolation regions 51. Hence, their positional relationship and sizes are determined.

In any case, in the above-described bipolar transistor, with the fine device structure of isolation regions, it becomes necessary to increase the impurity concentrations in the well regions, or to suppress occurrence of latch-up. This inevitably leads to a decrease in current amplification factor (current gain).

If the fine device structure is further advanced, the well concentration tends to further increase and the current amplification factor further decreases.

Jpn. Pat. Appln. KOKAI Publication No. 2002-110811 discloses that a parasitic bipolar transistor is obtained by forming a well of a second conductivity type in a semiconductor substrate of a first conductivity type, and providing, in this well, diffusion regions of the first and second conductivity types, which are isolated from each other by STI.

### BRIEF SUMMARY OF THE INVENTION

According to a first aspect of the present invention, there is provided a vertical bipolar transistor which comprises: a semiconductor substrate having a first conductivity type; a first well region having a second conductivity type, the first well region being formed in the semiconductor substrate and operating as a collector region; a second well region having the first conductivity type, the second well region being provided on the first well region and operating as a base region; a third well region having the second conductivity type, the third well region being provided on the first well region and acting as a lead-out region of the collector region; an emitter region having the second conductivity type, the emitter region being provided in the second well region; an isolation structure provided on the second well region so as to define the emitter region; a base lead-out region having the first conductivity type, the base lead-out region being provided in the second well region so as to adjoin and surround the isolation structure; a first insulating isolation layer provided in the second and third wells so as to define, along with the isolation structure, the base lead-out region; a collector lead-out region having the second conductivity type, the collector lead-out region being provided in the third well region and adjoining the first insulating isolation layer; and a second insulating isolation layer provided in the third well region so as to define, along with the first insulating isolation layer, the collector lead-out region.

According to a second aspect of the invention, there is provided a vertical bipolar transistor which comprises a semiconductor substrate having a first conductivity type, the semiconductor substrate acting as a collector region; a well region having a second conductivity type, the well region being provided in the semiconductor substrate and acting as a base region; an emitter region having the first conductivity type; the emitter region being provided in the well region; an isolation structure provided on the well region so as to define the emitter region; a base lead-out region having the second conductivity type, the base lead-out region being provided in the well region so as to adjoin and surround the isolation structure; a first insulating isolation layer provided in the well region so as to define, along with the isolation structure, the base lead-out region; a collector lead-out region having the first conductivity type, the collector lead-out region being provided in the semiconductor substrate and adjoining the first insulating isolation layer; and a second insulating isolation layer provided in the semiconductor substrate so as to define, along with the first insulating isolation layer, the collector lead-out region.

According to a third aspect of the invention, there is provided a semiconductor device including a vertical bipolar transistor in which a source/drain region of a first conductivity type in a CMOS section is formed as an emitter region in a bipolar section, a first well region of a second conductivity type in the CMOS section is formed as a base region in the bipolar section, and one of a second well region of the first conductivity type and a semiconductor substrate of the first conductivity type in the CMOS section is formed as a collector region in the bipolar section, wherein the vertical bipolar transistor includes an isolation structure provided on the first well region so as to define the emitter region.

### BRIEF DESCRIPTION OF THE SEVERAL VIEWS OF THE DRAWING

FIG. 1 is a cross-sectional view that schematically shows a fabrication step of a manufacturing process of a vertical bipolar transistor, which is formed at the same time as a CMOSFET, according to an embodiment of the present invention;

FIG. 2 is a cross-sectional view that schematically shows a fabrication step of the manufacturing process of the vertical bipolar transistor, which is formed at the same time as the CMOSFET, according to the embodiment of the present invention;

FIG. 3 is a cross-sectional view that schematically shows a fabrication step of the manufacturing process of the vertical bipolar transistor, which is formed at the same time as the CMOSFET, according to the embodiment of the present invention;

FIG. 4 is a cross-sectional view that schematically shows a fabrication step of the manufacturing process of the vertical bipolar transistor, which is formed at the same time as the CMOSFET, according to the embodiment of the present invention;

FIG. 5 is a cross-sectional view that schematically shows a fabrication step of the manufacturing process of the vertical bipolar transistor, which is formed at the same time as the CMOSFET, according to the embodiment of the present invention;

FIG. 6 is a cross-sectional view that schematically shows the vertical bipolar transistor, which is formed at the same time as the CMOSFET, according to the embodiment of the present invention;

FIG. 7 is a plan view that schematically shows the vertical bipolar transistor according to the embodiment of the invention;

FIG. 8 shows an example of measurement results of current amplification factors (hFE) of the vertical bipolar transistor of the present invention and the prior art;

FIG. 9 shows device simulation results of the vertical bipolar transistor of the present invention and the prior art;

FIG. 10 shows a result of evaluation by actual measurement with respect to the relationship between the width of a polysilicon film and hFE;

FIG. 11 shows an actual measurement result of an emitter-base breakdown voltage in relation to the width of the polysilicon film;

FIG. 12 is a cross-sectional view that schematically shows a vertical bipolar transistor that is formed at the same as a CMOSFET, according to an embodiment of the present invention;

FIG. 13 a cross-sectional view that schematically shows a fabrication step of a manufacturing process of a prior-art vertical bipolar transistor;

FIG. 14 is a cross-sectional view that schematically shows a fabrication step of the manufacturing process of the prior-art vertical bipolar transistor;

FIG. 15 is a cross-sectional view that schematically shows a fabrication step of the manufacturing process of the prior-art vertical bipolar transistor;

FIG. 16 is a cross-sectional view that schematically shows the prior-art vertical bipolar transistor; and

FIG. 17 is a plan view that schematically shows the prior-art vertical bipolar transistor.

### DETAILED DESCRIPTION OF THE EMBODIMENTS

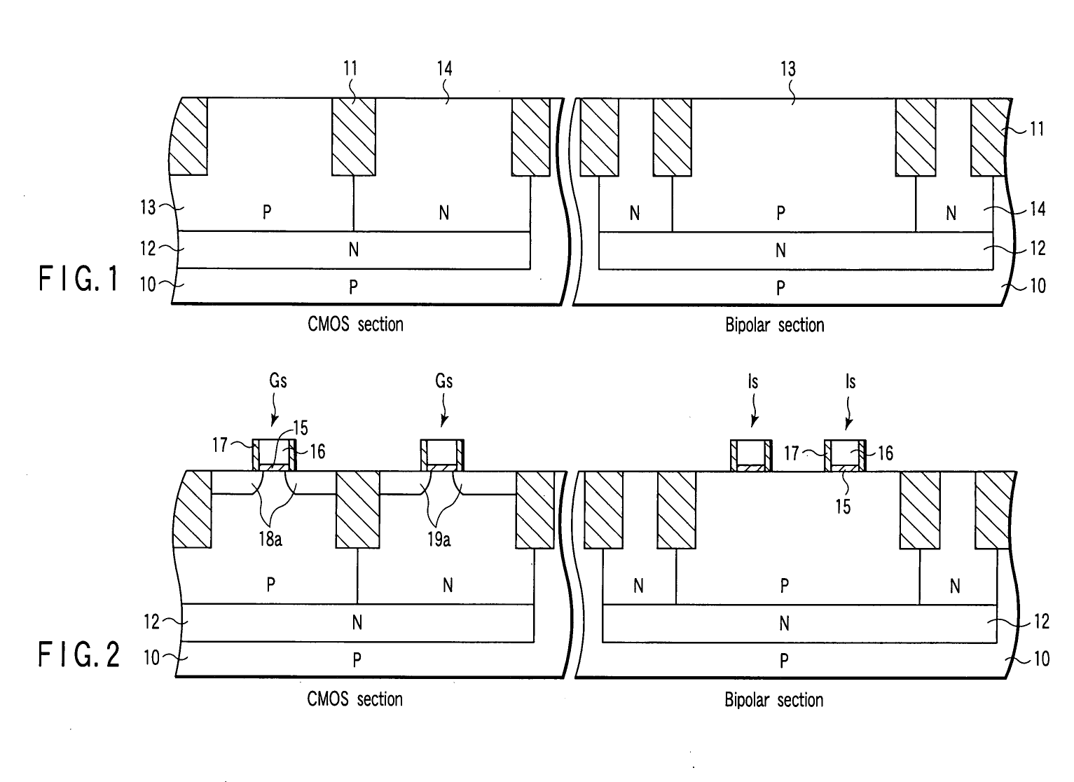

Referring now to FIGS. 1 to 7, a description is given of the structure of a vertical NPN bipolar transistor, as well as a method of manufacturing a MOS transistor in a CMOS section.

As is shown in FIG. 1, isolation regions 11 are selectively formed by STI so as to define a first region for a CMOS section and a second region for a bipolar section in a P-type silicon substrate 10. Then, using ion implantation, a deep N-type well region 12, which functions as a collector region of the bipolar transistor, a P-type well region 13, which functions as a base region, and an N-type well region 14, which becomes a lead-out region for the collector region, are formed. As will be described below, an N-channel MOSFET is formed in the P-type well region 13 of the CMOS section, and a P-channel MOSFET is formed in the N-type well region 14 of the CMOS section.

As illustrated in FIG. 2, a gate structure Gs is formed by a gate electrode forming process in the CMOS section. At the same time as the gate electrode forming process, a gate structure is formed as an isolation structure Is, which defines an emitter region of the bipolar transistor and isolates the emitter region from a base region. The gate structure comprises a gate insulation film 15, a polysilicon film 16 and a side wall insulation film 17.

In the CMOS section, N-type and P-type impurities are successively implanted for relaxation of electric field and characteristic control in the vicinity of the drain, thereby forming n⁻ extension portions 18a and p⁻ extension portions 19a. The extension ion implantation may be performed in the bipolar section, too, if the characteristics of the bipolar transistor are not greatly affected. In this embodiment, such ion implantation is not performed. The n⁻ extension portions 18a and p⁻ extension portions 19a are formed prior to the formation of the side wall insulation film 17, as in ordinary fabrication processes.

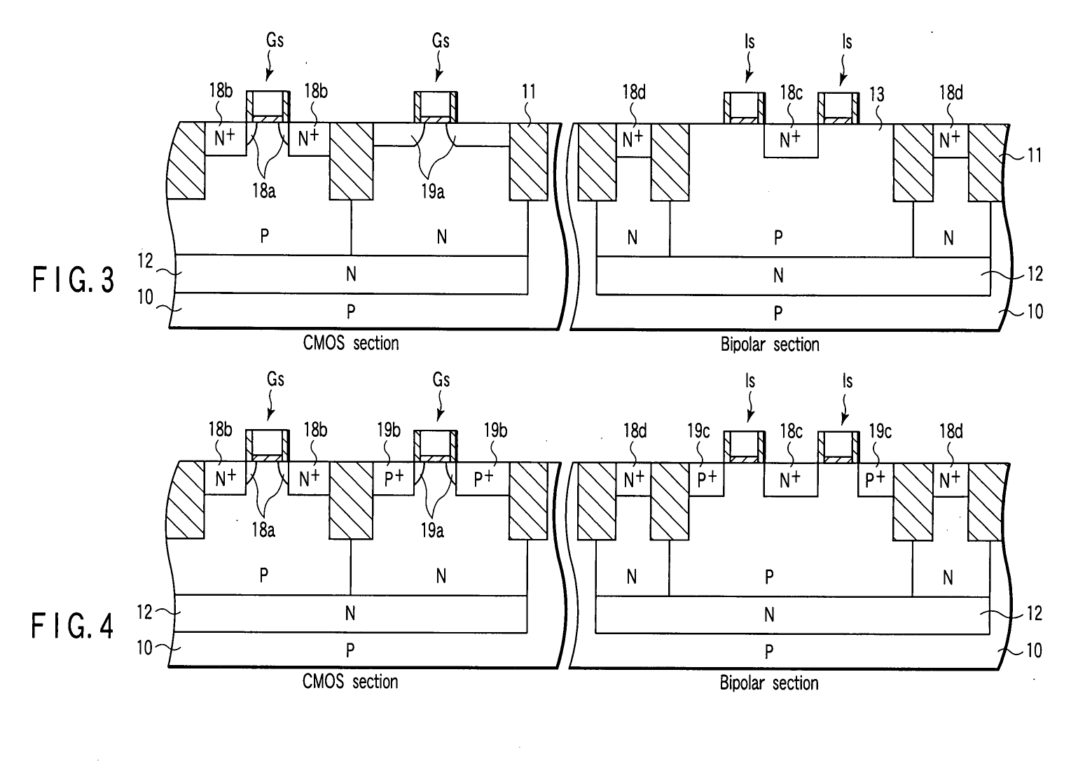

As shown in FIG. 3, at the same time as source/drain N⁺ regions 18b of the N-channel MOSFET in the CMOS section are formed, an N⁺ emitter region 18c and an N⁺ collector lead-out region 18d are selectively formed in the same step.

As is depicted in FIG. 4, at the same time as source/drain P⁺ regions 19b of the P-channel MOSFET in the CMOS section are formed and, a P⁺ base lead-out 19c is selectively formed in the same step.

The aforementioned N⁺/P⁺ regions are formed through a series of steps such as lithography, ion implantation and activation. In this case, resist boundaries for lithography are offset so as to prevent overlapping of N⁺ ion implantation and P⁺ ion implantation, relative to a reference pattern center in the polysilicon film 16. This aims at avoiding abnormal formation of silicide on the polysilicon film 16 in which N⁺/P⁺ impurities are implanted.

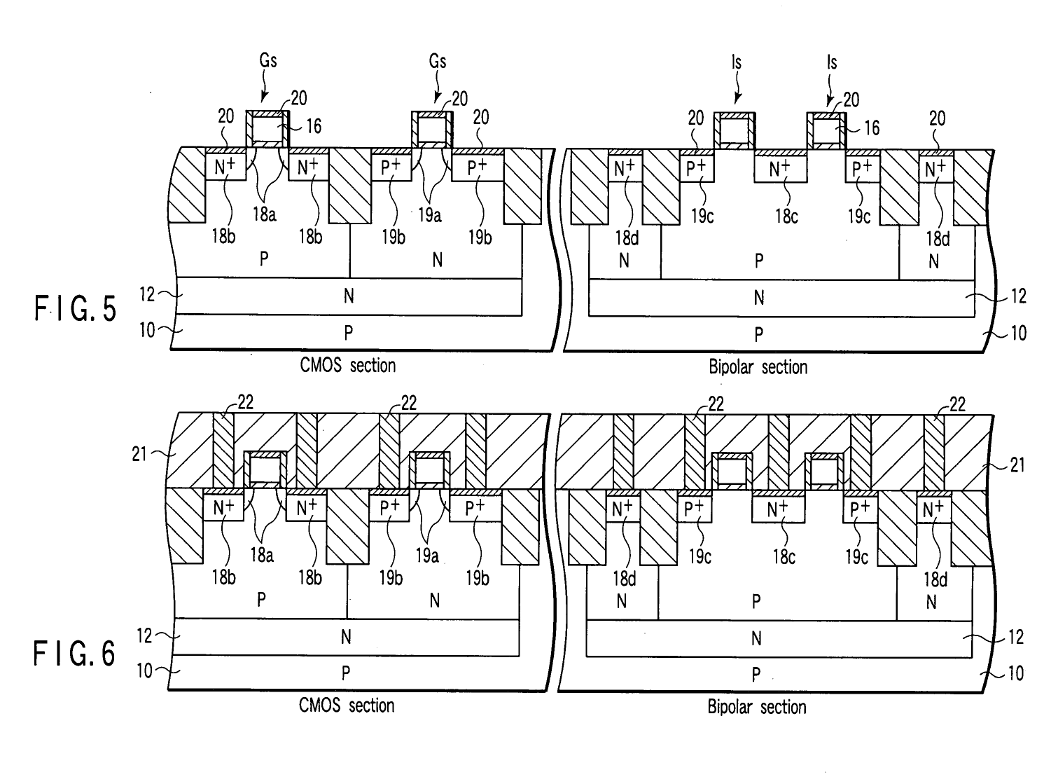

As shown in FIG. 5, silicide films 20 are formed by a saliciding process on the diffusion regions 18b to 18d, 19b and 19c as well as on the polysilicon film 16.

As is shown in FIG. 6, after an insulation film 21 is deposited over the substrate surface, conductor layers 22, which are connected to the N⁺ regions 18b to 18d and P⁺ regions 19b and 19c, are formed in the insulation film 21. Thus, the bipolar transistor including the CMOS section is completed.

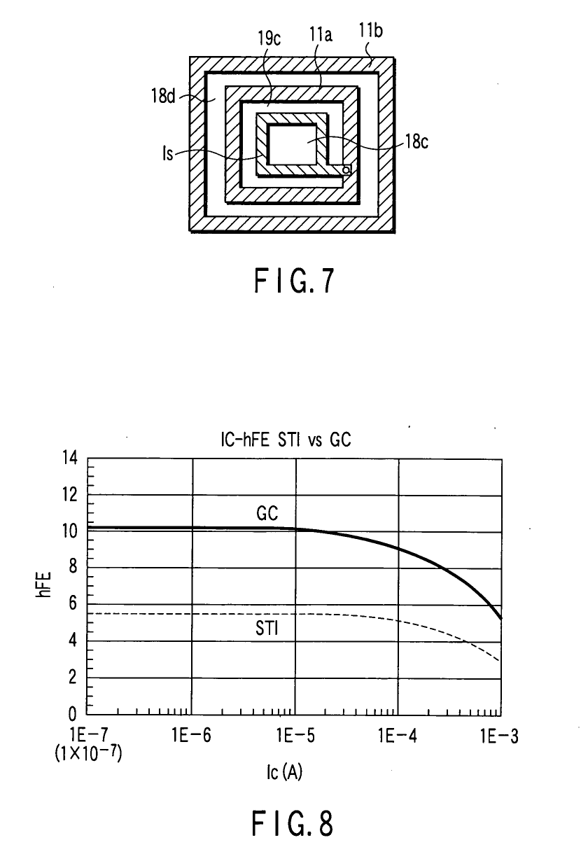

In the bipolar section, as shown in FIG. 7, the isolation structure Is, which is present within an inner isolation region 11a and comprises the gate insulation film 15, polysilicon film 16 and side wall insulation film 17, defines the distance between the emitter region 18c and the P⁺ base lead-out region 19c and the size of the emitter region 18c.

In the saliciding step, the side wall insulation film 17 effects isolation between silicide films. In the outer isolation region 11b, the P⁺ base lead-out region 19c and the N⁺ collector lead-out region 18d are isolated and their positional relationship is determined.

In this case, if further processing is not performed, the gate electrode 16 would be set in the floating state. To avoid this, a contact is formed on the isolation region 11a, and the gate electrode 16 is electrically connected to the emitter electrode or the base electrode by wiring. The position of the contact is not limited on the isolation region 11a. The contact may be directly formed on the gate electrode 16.

Next, the characteristic improvement effect of the device structure will be explained in comparison with the prior art. FIG. 8 shows an example of measurement results of current amplification factors (hFE) of the present invention (hereinafter referred to as “GC (Gate Conductor) type”) and the prior art (hereinafter “STI type”). As is clear from FIG. 8, the GC type can achieve an increased hFE that is about double that of the STI type.

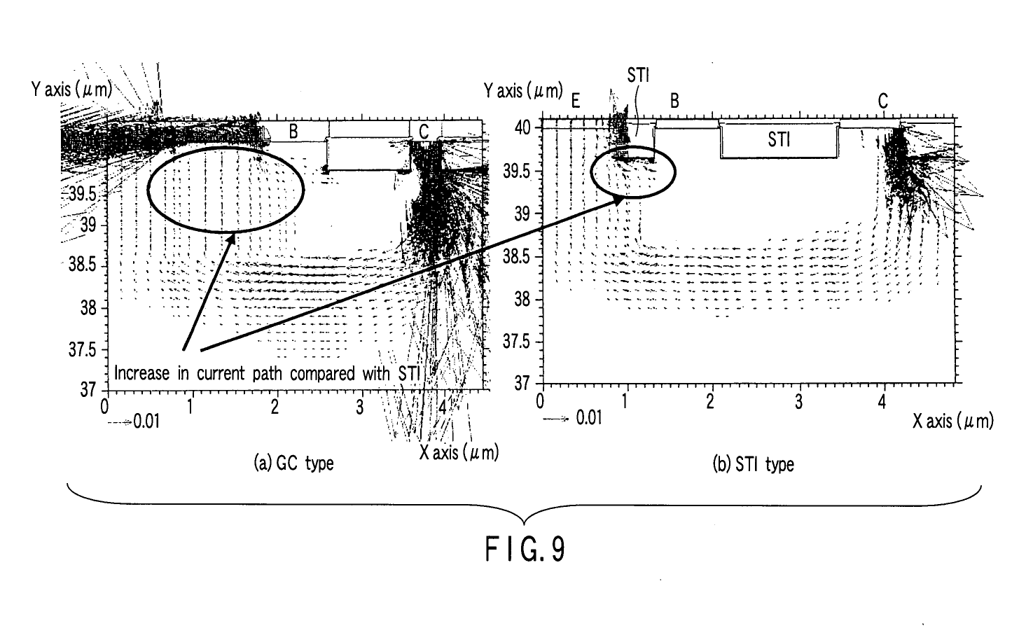

FIG. 9 shows device simulation results of these structures. In FIG. 9, (a) indicates the GC type, and (b) the STI type. The hFE is expressed by hFE=Ic/Ib. In actual measurement, a difference in base current is small. Improvement is attained by the increase in collector current. The simulation indicates that the current path (electrons) increases at the lower part and edge part of the polysilicon in the gate structure, as shown by circles in FIG. 9.

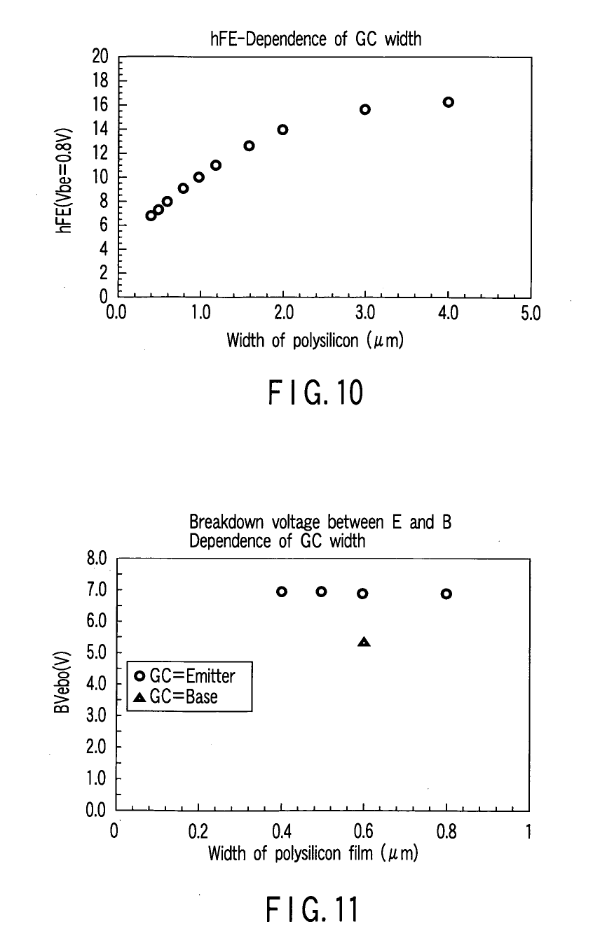

It is expected that since the silicon region at the lower part of the polysilicon contributes as the current path, the degree of improvement in hFE varies depending on the width of the polysilicon. FIG. 10 shows a result of evaluation by actual measurement with respect to the relationship between the width of the polysilicon film and hFE.

In the actual measurement, the width of the polysilicon film is varied in a range between 0.4 μm and 4.0 μm. Compared to the STI type, the hFE is improved over the entire range. With the width of 0.4 μm, the hFE increases 1.3 times. With the width of 1.0 μm, the hFE increases 2.1 times. With the width of 4.0 μm, the hFE increases about 3.2 times. The width of the polysilicon film defines the distance between the base lead-out region 19c and emitter region 18c. If this width increases, degradation in characteristics occurs due to an increase in emitter crowding phenomenon, which results from a voltage effect in the base region under the polysilicon layer. Moreover, the increase in width leads to an increase in area. It is not possible, therefore, to increase the width excessively. The width of the polysilicon film is determined in consideration of an increase in area of the circuit that is used, and the improvement in characteristics. In usual cases, it is difficult to think of the use of many bipolar transistors. No problem arises if the width is set up to about 2.0 μm. This value leads to double the area of the STI type that has been studied. The hFE that depends on the emitter size was constant, regardless of the value of the size.

If the emitter-base distance is too small, deterioration occurs in the emitter-base breakdown voltage. The polarity of the gate electrode changes depending on whether the potential of the gate electrode is made equal to that of the emitter or made equal to that of the base. It can be thought that the breakdown voltage may vary due to induction of an undesirable channel or gate leak.

FIG. 11 shows an actual measurement result of an emitter-base breakdown voltage in relation to the width of the polysilicon film. In the measurement, the width of the polysilicon film was varied in a range between 0.4 μm and 0.8 μm. At the width of 0.6 μm, comparison was made with the fixed potential of the polysilicon. The comparison result shows that there is no particular degradation in breakdown voltage at the width of 0.4 μm. Further, it turned out that the emitter-base breakdown voltage is higher when the potential of the polysilicon film is made equal to that of the emitter than when the potential of the polysilicon film is made equal to that of the base.

As has been described above, in the prior art, when a bipolar device is formed in the CMOS process, STI isolation has been used to isolate the emitter, base and collector. By contrast, in the present invention, emitter-base isolation is effected by the gate electrode, thereby enhancing the current amplification factor. Since the gate electrode is indispensable in the CMOS process, this displacement can easily be performed and an increase in the range of applications is expectable. Although a further decrease in hFE is likely in future fine device structure, double or more hFE can be obtained without the need to add special fabrication steps.

In the meantime, since it is necessary to isolate the emitter or the base by the gate oxide film and the side wall insulation film formed at the gate electrode side walls, the bipolar device of this embodiment should preferably use a gate oxide film that permits only a low gate leak, with use of a power supply voltage of up to about 1.5 V. In recent years, a plurality of gate oxide films are used in usual cases. This does not narrow the range of applications of the present embodiment.

The present embodiment has been described with respect to the NPN bipolar transistor. If impurities of opposite conductivity type are introduced into a P-type semiconductor substrate at the time of manufacture, a PNP bipolar transistor can be obtained.

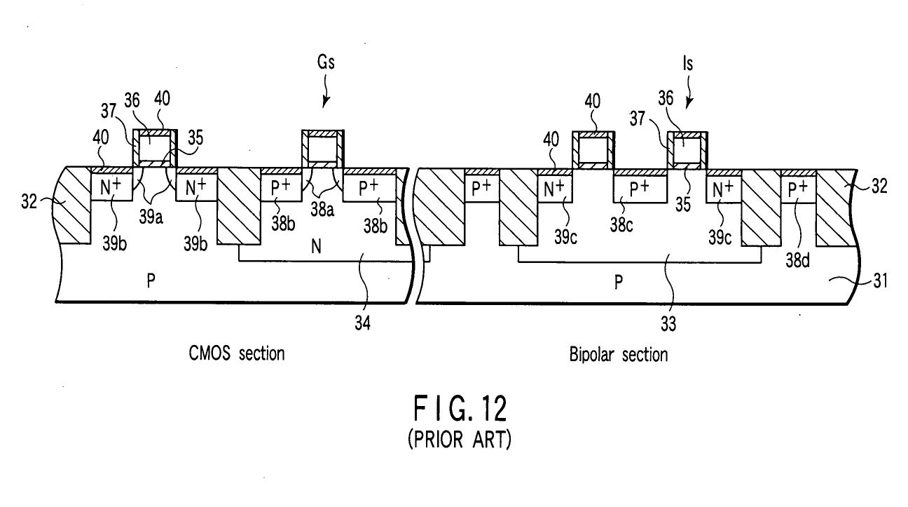

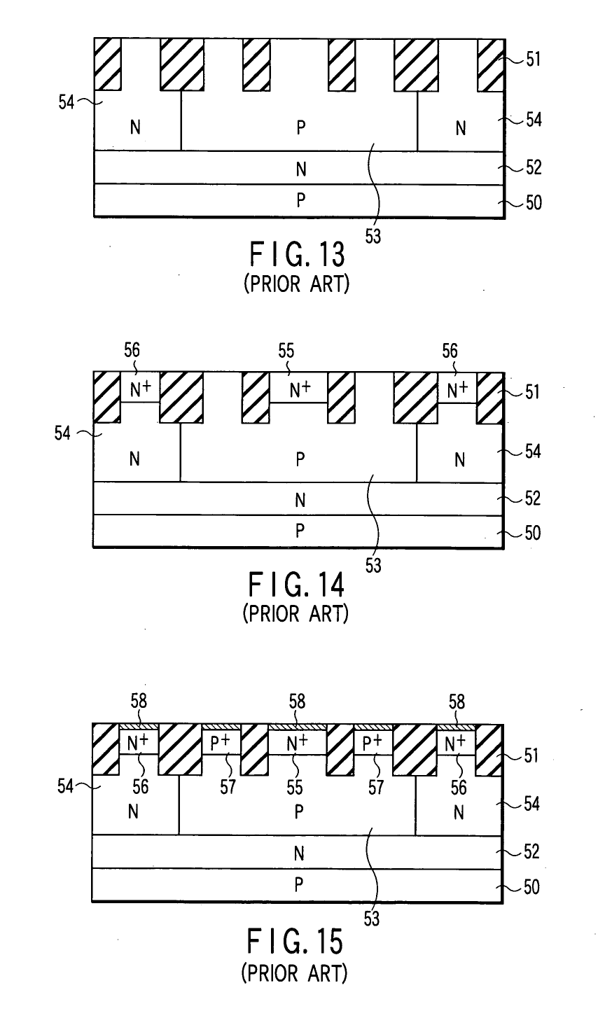

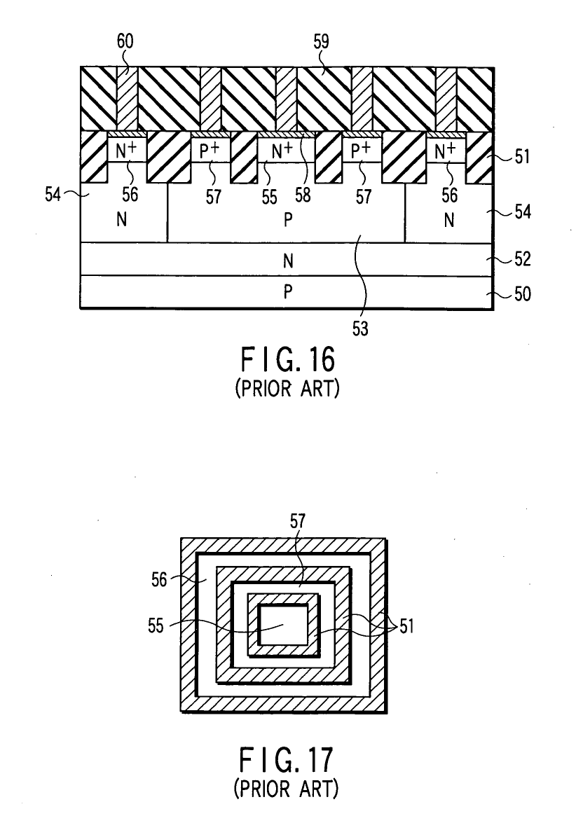

Specifically, as shown in FIG. 12, isolation regions 32 are selectively formed by STI so as to form a first region for a CMOS section and a second region for a bipolar section in a P-type silicon substrate 31. Then, using ion implantation, an N-type well region 33, which functions as a base region of the bipolar transistor, and an N-type well region 34 of the CMOS section are selectively formed. An N-channel MOSFET is formed in the P-type silicon substrate 31 of the CMOS section, and a P-channel MOSFET is formed in the N-type well region 34 of the CMOS section.

Like the above-described NPN bipolar transistor, a gate structure Gs is formed by a gate electrode forming process in the CMOS section. At the same time as the gate electrode forming process, a gate structure is formed as an isolation structure Is, which defines an emitter region of the bipolar transistor and isolates the emitter region from the base region. The gate structure comprises a gate insulation film 35, a polysilicon film 36 and a side wall insulation film 37.

In the CMOS section, P-type impurity is ion-implanted for relaxation of electric field and characteristic control in the vicinity of the drain, thereby forming p⁻ extension portions 38a. At the same time as formation of source/drain P⁺ regions 38b of the P-channel MOSFET, a P⁺ emitter region 38c and a P⁺ collector lead-out region 38d are selectively formed.

Following formation of n⁻ extension portions 39a in the CMOS section, source/drain N⁺ regions 39b of the N-channel MOSFET and an N⁺ base lead-out region 39c are selectively formed at the same time. Then, silicide films 40 are formed by a saliciding process on the diffusion regions 38b to 38d, 39b and 39c and the polysilicon films 36. Although illustration of formation of electrodes is omitted, the PNP bipolar transistor including the CMOS section is thus obtained.

In this PNP bipolar transistor, like the NPN bipolar transistor, the emitter-base isolation is effected by the gate structure of the CMOS section. Therefore, the same advantageous effects can be obtained.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

1. A vertical bipolar transistor comprising:
a semiconductor substrate having a first conductivity type;
a first well region having a second conductivity type, the first well region being formed in the semiconductor substrate and operating as a collector region;
a second well region having the first conductivity type, the second well region being provided on the first well region and operating as a base region;
a third well region having the second conductivity type, the third well region being provided on the first well region and acting as a lead-out region of the collector region;
an emitter region having the second conductivity type, the emitter region being provided in the second well region;
an isolation structure provided on the second well region so as to define the emitter region;
a base lead-out region having the first conductivity type, the base lead-out region being provided in the second well region so as to adjoin and surround the isolation structure;
a first insulating isolation layer provided in the second and third wells so as to define, along with the isolation structure, the base lead-out region;
a collector lead-out region having the second conductivity type, the collector lead-out region being provided in the third well region and adjoining the first insulating isolation layer; and
a second insulating isolation layer provided in the third well region so as to define, along with the first insulating isolation layer, the collector lead-out region.

2. The vertical bipolar transistor according to claim 1, wherein the isolation structure comprises a gate structure in a MOS transistor including a gate insulation film, a gate electrode, and a side wall formed on a peripheral side surface of the gate electrode.

3. The vertical bipolar transistor according to claim 2, wherein the width of the gate electrode is in a range between 0-4 μm and 2.0 μm.

4. The vertical bipolar transistor according to claim 1, wherein each of the first and second insulating isolation layers comprises an insulation layer formed by an STI technique.

5. The vertical bipolar transistor according to claim 1, wherein a silicide film is provided on each of the emitter region, the base lead-out region, the collector lead-out region and the gate electrode.

6. A vertical bipolar transistor comprising:
a semiconductor substrate having a first conductivity type, the semiconductor substrate acting as a collector region;
a well region having a second conductivity type, the well region being provided in the semiconductor substrate and acting as a base region;
an emitter region having the first conductivity type, the emitter region being provided in the well region;
an isolation structure provided on the well region so as to define the emitter region;
a base lead-out region having the second conductivity type, the base lead-out region being provided in the well region so as to adjoin and surround the isolation structure;
a first insulating isolation layer provided in the well region so as to define, along with the isolation structure, the base lead-out region; a collector lead-out region having the first conductivity type, the collector lead-out region being provided in the semiconductor substrate and adjoining the first insulating isolation layer; and
a second insulating isolation layer provided in the semiconductor substrate so as to define, along with the first insulating isolation layer, the collector lead-out region.

7. The vertical bipolar transistor according to claim 6, wherein the isolation structure comprises a gate structure in a MOS transistor including a gate insulation film, a gate electrode, and a side wall formed on a peripheral side surface of the gate electrode.

8. The vertical bipolar transistor according to claim 6, wherein the width of the gate electrode is in a range between 0.4 μm and 2.0 μm.

9. The vertical bipolar transistor according to claim 6, wherein each of the first and second insulating isolation layers comprises an insulation layer formed by an STI technique.

10. The vertical bipolar transistor according to claim 6, wherein a silicide film is provided on each of the emitter region, the base lead-out region, the collector lead-out region and the gate electrode.

11. A semiconductor device comprising a vertical bipolar transistor in which a source/drain region of a first conductivity type in a CMOS section is formed as an emitter region in a bipolar section, a first well region of a second conductivity type in the CMOS section is formed as a base region in the bipolar section, and one of a second well region of the first conductivity type and a semiconductor substrate of the first conductivity type in the CMOS section is formed as a collector region in the bipolar section,
wherein the vertical bipolar transistor includes an isolation structure provided on the first well region so as to define the emitter region.

12. The semiconductor device according to claim 11, wherein the isolation structure comprises a gate insulation film, a gate electrode, and a side wall formed on a peripheral side surface of the gate electrode in the CMOS section.

13. The semiconductor device according to claim 12, wherein the gate electrode is so connected as to have a potential equal to a potential of one of the emitter region and the base region.

14. The semiconductor device according to claim 12, wherein a gate oxide film for providing a gate structure has such a thickness that the gate oxide film is used with a power supply voltage of the CMOS section, which is higher than 1.5 V.

15. The semiconductor device according to claim 12, wherein the width of the gate electrode is in a range between 0.4 μm and 2.0 μm.

16. The semiconductor device according to claim 12, further comprising first and second insulating isolation layers each including an insulation layer formed by an STI technique.

17. The semiconductor device according to claim 11, further comprising a base lead-out region and a collector lead-out region in addition to the emitter region and the gate electrode and including a silicide film provided on each of the emitter region, the base lead-out region, the collector lead-out region and the gate electrode.

18. A method of manufacturing a vertical bipolar transistor, comprising:
selectively forming a plurality of isolation regions by an STI technique in a semiconductor substrate having a first conductivity type;
introducing impurities successively into the semiconductor substrate to provide selectively a first well region having a second conductivity type and acting as a collector region, a second well region having the first conductivity type and acting as a base region, and a third well region having the second conductivity type and acting as a lead-out region of the collector region;
forming a gate structure comprising a gate insulation film, a polysilicon film and a side wall insulation film on the second well region so as to define the emitter region having the second conductivity type, to provide an isolation structure;
forming at the same time the emitter region provided in the second well region and defined by the isolation structure, and a collector lead-out region having the second conductivity type, the collector lead-out region being provided in the third well region and being defined by the isolation region; and
forming a base lead-out region having the first conductivity type, the base lead-out region being provided in the second well region and being defined by the isolation structure and the isolation regions.

19. A method of manufacturing a vertical bipolar transistor, comprising:
selectively forming a plurality of insulating isolation regions by an STI technique in a semiconductor substrate having a first conductivity type;
introducing impurities into the semiconductor substrate to provide selectively a first well region having a second conductivity type and acting as a base region of a bipolar section, and a second well region having the second conductivity type for forming a CMOS section;
forming, simultaneously with a gate structure forming process in the CMOS section, a gate structure comprising a gate insulation film, a polysilicon film and a side wall insulation film on the first well region so as to define an emitter region, thereby forming an isolation structure;
forming, simultaneously with a source/drain region forming process in the CMOS section, the emitter region defined in the first well region by the isolation structure; and
forming, simultaneously with the source/drain region forming process in the CMOS section, a base lead-out region having the second conductivity type and defined in the first well region by the isolation structure and the insulating isolation regions.

20. A method of manufacturing a semiconductor device, comprising:
selectively forming a plurality of isolation regions by an STI technique in a semiconductor substrate having a first conductivity type;
introducing impurities successively into the semiconductor substrate, thus selectively forming a first well region of a second conductivity type in a CMOS section, a second well region of the first conductivity type on the first well region therein, and a third well region of the second conductivity type on the first well region therein, and also selectively forming a fourth well region of the second conductivity type, which acts as a collector region in a bipolar section, a fifth well region of the first conductivity type, which lies on the fourth well region and acts as a base region, and a sixth well region of the second conductivity type, which acts as a lead-out region of the collector region;
forming, simultaneously with a gate structure forming process in the CMOS section, a gate structure comprising a gate insulation film, a polysilicon film and a side wall insulation film on the fifth well region so as to define an emitter region, thereby forming an isolation structure;
forming, simultaneously with a source/drain region forming process in the CMOS section, the emitter region of the second conductivity type defined in the fifth well region by the isolation structure, and a collector lead-out region of the second conductivity type defined in the sixth well region by the isolation regions; and
forming, simultaneously with the source/drain region forming process in the CMOS section, a base lead-out region of the first conductivity type defined in the fifth well region by the isolation structure and the isolation regions.
